(19) United States
(12) Patent Application Publication
(10) Pub. No.: US 2025/0298311 A1
(43) Pub. Date: Sep. 25, 2025

(54) SEMICONDUCTOR PHOTORESIST COMPOSITION AND METHODS OF FORMING PATTERNS USING THE COMPOSITION

(71) Applicant: SAMSUNG SDI CO., LTD., Yongin-si (KR)

(72) Inventors: Soobin LIM, Suwon-si (KR); Young Keun KIM, Suwon-si (KR); Minhye KIM, Suwon-si (KR); Sukil KANG, Suwon-si (KR); Dong Wan RYU, Suwon-si (KR)

(21) Appl. No.: 19/030,786

(22) Filed: Jan. 17, 2025

(30) Foreign Application Priority Data
Mar. 21, 2024 (KR) 10-2024-0039349

(51) Int. Cl. G03F 7/004; C07F 7/22; G03F 7/00; G03F 7/20; H01L 21/027; H01L 21/311; H01L 21/3213

(52) U.S. Cl. CPC G03F 7/0042; C07F 7/2224; G03F 7/2002; G03F 7/70033; H01L 21/0271; H01L 21/31144; H01L 21/32139

(57) ABSTRACT

A semiconductor photoresist composition and a method of forming or providing patterns using the semiconductor photoresist composition are disclosed. The semiconductor photoresist composition may include a first organometallic compound represented by Chemical Formula 1, a second organometallic compound represented by Chemical Formula 2, and a solvent.

### CROSS-REFERENCE TO RELATED APPLICATIONS

The present application claims priority to and the benefit of Korean Patent Application No. 10-2024-0039349, filed on Mar. 21, 2024, in the Korean Intellectual Property Office, the entire disclosure of which is incorporated herein by reference.

### BACKGROUND

### 1. Field

One or more embodiments of the present disclosure relate to a semiconductor photoresist composition and a method of forming or providing patterns using the semiconductor photoresist composition.

### 2. Description of the Related Art

Extreme ultraviolet (EUV) lithography has drawn much attention as one essential technology for manufacturing a next generation semiconductor device (e.g., a semiconductor chip). The EUV lithography is a pattern-forming technology using an EUV ray that has a wavelength of 13.5 nm as an exposure light source. According to the EUV lithography, a fine pattern (e.g., less than or equal to 20 nm) may be formed or provided in an exposure process during a manufacturing of a semiconductor device (e.g., a semiconductor chip).

The extreme ultraviolet (EUV) lithography is realized through development of compatible photoresists which may be performed at a spatial resolution of less than or equal to 16 nm. Efforts to satisfy insufficient specifications of chemically amplified (CA) photoresists, such as a resolution, a photospeed, and feature roughness (or also referred to as a line edge roughness or LER), for the next generation device have been or are being made.

An intrinsic image blurring due to an acid-catalyzed reaction in the polymer-type or kind photoresists limits a resolution in small feature sizes, which has existed in electron beam (e-beam) lithography. The chemically amplified (CA) photoresists are designed for high sensitivity. However, because their elemental makeups reduce light absorbance of the photoresists at a wavelength of 13.5 nm, it may decrease their sensitivity, and the chemically amplified (CA) photoresists may have more difficulties under an EUV exposure.

The CA photoresists may have difficulties with respect to small feature sizes due to roughness issues, and line edge roughness (LER) of the CA photoresists experimentally may be increased, as a photospeed may be decreased partially due to an essence of acid catalyst processes. Accordingly, a novel high-performance photoresist is desired or required in a semiconductor industry because of these defects and problems of the CA photoresists.

In order to overcome the aforementioned drawbacks of the chemically amplified (CA) organic photosensitive composition, an inorganic photosensitive composition has been researched. The inorganic photosensitive composition has been mainly or predominantly used for negative tone patterning which has resistance against removal by a developer composition due to chemical modification through nonchemical amplification mechanism. The inorganic composition includes an inorganic element that has a higher EUV absorption rate than hydrocarbon, and thus, it may secure sensitivity through the nonchemical amplification mechanism and may be less sensitive with respect to a stochastic effect and thus may have low line edge roughness and a relatively smaller number of defects.

Inorganic photoresists based on peroxopolyacids of tungsten mixed with tungsten, niobium, titanium, and/or tantalum have been reported as radiation sensitive materials for patterning.

These materials are effective for patterning large pitches for bilayer configuration as far ultraviolet (deep UV), X-ray, and electron beam sources. When cationic hafnium metal oxide sulfate (HfSOx) materials along with a peroxo complexing agent was used to image a 15 nm half-pitch (HP) through projection EUV exposure, improved performance was obtained. This system exhibits a high performance of a non-CA photoresist and has a practicable photospeed near to a requirement for an EUV photoresist. However, the hafnium metal oxide sulfate material including the peroxo complexing agent has some practical drawbacks. First, these materials are coated in a mixture of corrosive sulfuric acid/hydrogen peroxide and have insufficient shelf-life stability. Second, a structural change of the materials for performance improvement as a composite mixture is challenging. Third, development should be performed in a tetramethylammonium hydroxide (TMAH) solution at a high concentration of 25 wt % and/or the like.

To address these issues, research has been focused on developing molecules that include tin (Sn), which have excellent or suitable absorption of extreme ultraviolet rays. As for an organic tin polymer among the molecules containing tin, alkyl ligands are dissociated by light absorption or secondary electrons produced. The dissociated alkyl ligands are then crosslinked with adjacent chains through oxo bonds, and thus, enable the negative tone patterning which may not be removed by an organic developer. Although this organic tin polymer exhibits greatly improved sensitivity and maintains a desired resolution and line edge roughness, the patterning characteristics need to be further improved for commercial availability.

### SUMMARY

One or more aspects of embodiments of the present disclosure are directed toward a semiconductor photoresist composition having excellent or suitable coating properties and/or line edge roughness (LER).

One or more aspects of embodiments of the present disclosure are directed toward a method of forming or providing patterns using the semiconductor photoresist composition.

Additional aspects will be set forth in part in the description which follows and, in part, will be apparent from the description, or may be learned by practice of the presented embodiments of the disclosure.

A semiconductor photoresist composition according to one or more embodiments may include a first organometallic compound represented by Chemical Formula 1, a second organometallic compound represented by Chemical Formula 2, and a solvent.

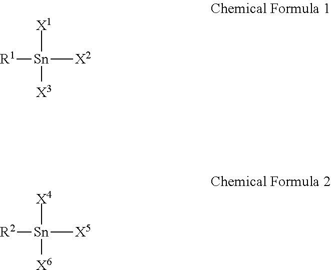

In Chemical Formula 1 and Chemical Formula 2,

R¹ and R² may each independently be a substituted or unsubstituted C1 to C20 alkyl group, a substituted or unsubstituted C2 to C20 alkenyl group, a substituted or unsubstituted C2 to C20 alkynyl group, or -L^{a}-O—R^{a} (wherein L^{a} may be a single bond (e.g., a single covalent bond) or a substituted or unsubstituted C1 to C20 alkylene group, and R^{a} may be a substituted or unsubstituted C1 to C20 alkyl group),

X¹ to X³ may each independently be selected from among an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), and a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), and

X⁴ to X⁶ may each independently be selected from among an amino, alkylamine, or dialkylamine group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an amido group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an amidinate group (—NR^{h}C(NRⁱ)R^{j}, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an alkylthio or arylthio group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), a phosphinate group (—OP(O)OR^{m}Rⁿ, wherein R^{m} and Rⁿ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), and a sulfonate group (—OS(O)₂R^{o}, wherein R^{o} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof).

A method of forming or providing patterns according to one or more embodiments may include forming or providing an etching-objective layer on a substrate, coating the semiconductor photoresist composition on the etching-objective layer to form or provide a photoresist layer, patterning the photoresist layer to form or provide a photoresist pattern, and etching the etching-objective layer utilizing the photoresist pattern as an etching mask.

The semiconductor photoresist composition according to one or more embodiments may provide a photoresist pattern having excellent or suitable coating properties and LER.

### BRIEF DESCRIPTION OF THE DRAWINGS

The above and other aspects and features of certain embodiments of the present disclosure will be more apparent from the following description taken in conjunction with the accompanying drawings, in which:

FIGS. 1A-1E each is a cross-sectional view illustrating a method of forming or providing patterns using a semiconductor photoresist composition according to one or more embodiments.

### DETAILED DESCRIPTION

Hereinafter, referring to the drawings, one or more embodiments of the present disclosure are described in more detail. In the following description of the present disclosure, the functions or constructions that should be generally understood by a person of ordinary skill in the art may not be described in order to clarify the present disclosure.

In order to clearly illustrate embodiments of the present disclosure, certain description and relationships may be omitted, and throughout the present disclosure, substantially the same or similar configuration elements may be designated by the same reference numerals. Also, because the size and thickness of each configuration shown in the drawings may be arbitrarily shown for better understanding and ease of description, embodiments of the present disclosure are not necessarily limited thereto.

As utilized herein, the terms “and/or” and “or” may include any and all combinations of one or more of the associated listed items. Expressions, such as “at least one of,” when preceding a list of elements, modify the entire list of elements and do not modify the individual elements of the list.

It will be further understood that the terms “comprise”, “include,” or “have/has,” when utilized in the present disclosure, specify the presence of stated features, integers, steps, operations, elements, and/or components, but do not preclude the presence or addition of one or more other features, integers, steps, operations, elements, components, and/or groups thereof. The “/” utilized below may be interpreted as “and” or as “or” depending on the situation.

As utilized herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure”.

In the context of the present disclosure and unless otherwise defined, the terms “use,” “using,” and “used” may be considered synonymous with the terms “utilize,” “utilizing,” and “utilized,” respectively.

As utilized herein, the term “about,” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may refer to within one or more standard deviations, or within ±30%, 20%, 10%, or ±5% of the stated value.

Any numerical range recited herein is intended to include all sub-ranges of substantially the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the drawings, the thickness of layers, films, panels, regions, and/or the like, may be enlarged for clarity. In the drawings, the thickness of a part of layers or regions, and/or the like, may be exaggerated for clarity. It will be understood that if (e.g., when) an element, such as a layer, film, region, or substrate, is referred to as being “on” another element, it may be directly on the other element or intervening elements may also be present. If (e.g., when) an element is referred to as being “directly on” another element, there may be no intervening elements present.

As used herein, “substituted” refers to replacement of a hydrogen atom by deuterium, a halogen, a carboxyl group, a hydroxy group, a thiol group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen atom by another substituent and remaining of the hydrogen atom.

As used herein, if (e.g., when) a definition is not otherwise provided, “alkyl group” refers to a linear or branched aliphatic hydrocarbon group. The alkyl group may be “saturated alkyl group” without any double bond or triple bond.

The alkyl group may be a C1 to C10 alkyl group. For example, the alkyl group may be a C1 to C8 alkyl group, a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, “cycloalkyl group” refers to a monovalent cyclic aliphatic hydrocarbon group.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but embodiments of the present disclosure are not limited thereto.

As used herein, “aryl group” refers to a substituent in which all atoms in the cyclic substituent have a p-orbital and these p-orbitals are conjugated and may include a monocyclic or fused ring polycyclic (e.g., rings sharing adjacent pairs of carbon atoms) functional group.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

In the chemical formulas described herein, t-Bu refers to a tert-butyl group.

Hereinafter, a semiconductor photoresist composition according to one or more embodiments is described.

A semiconductor photoresist composition according to one or more embodiments may include a first organometallic compound represented by Chemical Formula 1, a second organometallic compound represented by Chemical Formula 2, and a solvent.

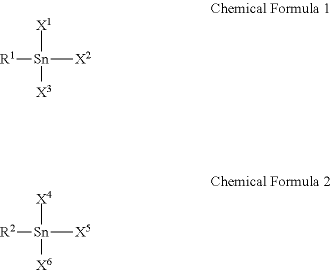

In Chemical Formula 1 and Chemical Formula 2,

R¹ and R² may each independently be a substituted or unsubstituted C1 to C20 alkyl group, a substituted or unsubstituted C2 to C20 alkenyl group, a substituted or unsubstituted C2 to C20 alkynyl group, or -L^{a}-O—R^{a} (wherein L^{a} may be a single bond (e.g., a single covalent bond) or a substituted or unsubstituted C1 to C20 alkylene group, and R^{a} may be a substituted or unsubstituted C1 to C20 alkyl group),

X¹ to X³ may each independently be selected from among an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), and a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), and

X⁴ to X⁶ may each independently be selected from among an amino, alkylamine, or dialkylamine group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an amido group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an amidinate group (—NR^{h}C(NRⁱ)Rⁱ, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an alkylthio or arylthio group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), a phosphinate group (—OP(O)OR^{m}Rⁿ, wherein R^{m} and Rⁿ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), and a sulfonate group (—OS(O)₂R^{o}, wherein R^{o} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof).

In a composition in which two or more types or kinds of organic tin compounds having different ligands are mixed, a degree of disorder of the entire composition system may increase, and the surface roughness after spin coating may be improved or enhanced.

The first organometallic compound may be an organometallic compound having a highly reactive ligand and may improve or enhance sensitivity (e.g., to provide suitable sensitivity) by promoting curing of the exposed region, and if (e.g., when) mixed with the second organometallic compound, curing of the non-exposed region may be suppressed, thereby improving the bridge margin, and crystallinity by the introduction of one or more suitable ligands may be reduced thereby achieving excellent or suitable coating properties and LER.

As an example, R¹ and R² may each independently be a substituted or unsubstituted C1 to C10 alkyl group, a substituted or unsubstituted C2 to C10 alkenyl group, a substituted or unsubstituted C2 to C10 alkynyl group, or -L^{a}-O—R^{a} (wherein L^{a} may be a single bond (e.g., a single covalent bond) or a substituted or unsubstituted C1 to C20 alkylene group, and R^{a} may be a substituted or unsubstituted C1 to C20 alkyl group),

X¹ to X³ may each independently be selected from among an alkoxy or aryloxy group (—OR^{b}, wherein R^{b} may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), and a carboxyl group (—O(CO)R^{c}, wherein R^{c} may be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), and

X⁴ to X⁶ may each independently be selected from among an amino, alkylamine, or dialkylamine group (—NR^{d}R^{e}, wherein R^{d} and R^{e} may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), an amido group (—NR^{f}(COR^{g}), wherein R^{f} and R^{g} may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), or an amidinate group (—NR^{h}C(NRⁱ)R^{j}, wherein R^{h}, Rⁱ, and R^{j} may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), an alkylthio or arylthio group (—SR^{k}, wherein R^{k} may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), a thiocarboxyl group (—S(CO)R^{l}, wherein R^{l} may be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), a phosphinate group (—OP(O)OR^{m}Rⁿ, wherein R^{m} and Rⁿ may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), and a sulfonate group (—OS(O)₂R^{o}, wherein R^{o} may be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof).

For example, R¹ and R² may each independently be a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted benzyl group, a substituted or unsubstituted methoxy group, a substituted or unsubstituted ethoxy group, a substituted or unsubstituted propoxy group, or a combination thereof,

R^{b} may be a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof, and

R^{c}, R^{d}, R^{e}, R^{f}, R^{g}, R^{h}, Rⁱ, R^{j}, R^{k}, R^{l}, R^{m}, Rⁿ, and R^{o} may each independently be hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof.

For example, X⁴ to X⁶ may each independently be selected from among an amino, alkylamine, or dialkylamine group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an amido group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), a phosphinate group (—OP(O)OR^{m}Rⁿ, wherein R^{m} and Rⁿ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), and a sulfonate group (—OS (O)₂R^{o}, wherein R^{o} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof).

In one or more embodiments, the first organometallic compound and the second organometallic compound may be included in a weight ratio of about 90:10 to about 40:60.

For example, the first organometallic compound and the second organometallic compound may be included in a weight ratio of about 80:20 to about 40:60, for example, about 70:30 to about 40:60.

The first organometallic compound may be selected from among the compounds listed in Group 1.

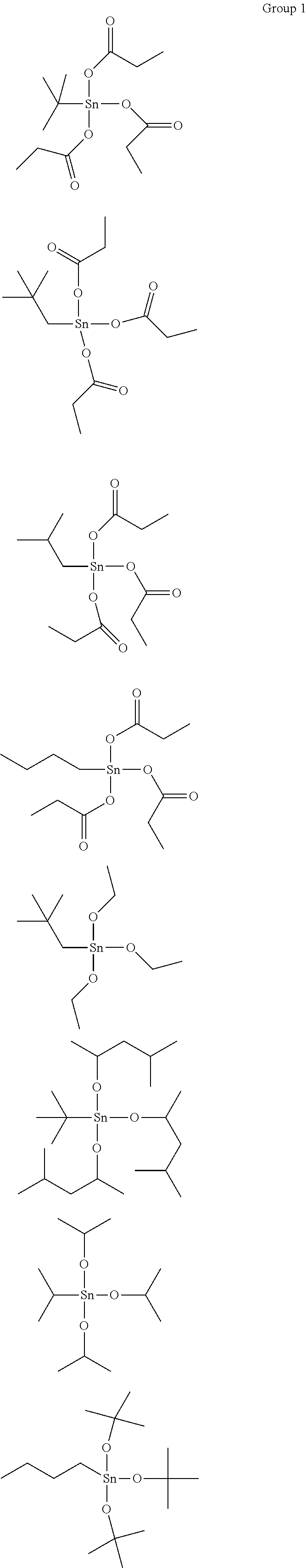

The second organometallic compound may be selected from among the compounds listed in Group 2.

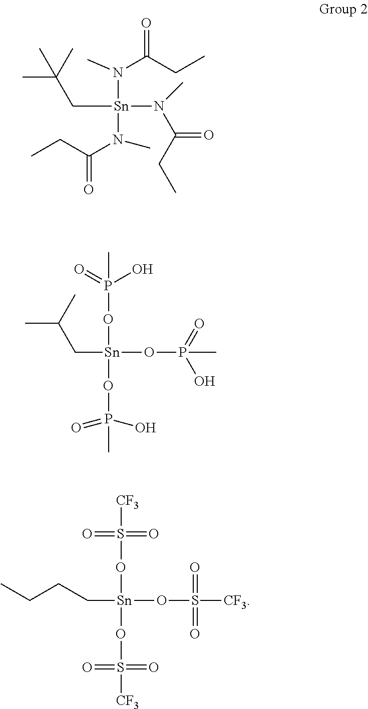

The organometallic compound may strongly absorb extreme ultraviolet light at 13.5 nm and may have excellent or suitable sensitivity to high-energy light.

In the semiconductor photoresist composition according to one or more embodiments, the first organometallic compound and the second organometallic compound may be included in an amount of about 1 wt % to about 30 wt %, for example, about 1 wt % to about 25 wt %, for example, about 1 wt % to about 20 wt %, for example, about 1 wt % to about 15 wt %, for example, about 1 wt % to about 10 wt %, for example, about 1 wt % to about 5 wt % based on 100 wt % of the semiconductor photoresist composition. If (e.g., when) the organometallic compounds are included in the amount within the above range, the storage stability and/or etch resistance of the composition for semiconductor photoresist may be improved or enhanced, and the resolution characteristics may be improved or enhanced.

As the semiconductor photoresist composition according to one or more embodiments may include the first organometallic compound and second organometallic compound as described in one or more embodiments, a semiconductor photoresist composition having excellent or suitable sensitivity and/or pattern formation properties may be provided.

The solvent included in the semiconductor photoresist composition according to one or more embodiments may be an organic solvent, and may be, for example, aromatic compounds (e.g., xylene, toluene, and/or the like), alcohols (e.g., 4-methyl-2-pentenol, 4-methyl-2-propanol, 1-butanol, methanol, isopropyl alcohol, 1-propanol, and/or the like), ethers (e.g., anisole, tetrahydrofuran, and/or the like), esters (n-butyl acetate, propylene glycol monomethyl ether acetate, ethyl acetate, ethyl lactate, and/or the like), ketones (e.g., methyl ethyl ketone, 2-heptanone, and/or the like), or a mixture thereof, but embodiments of the present disclosure are not limited thereto.

In one or more embodiments, the semiconductor photoresist composition may further include a resin in addition to the first organometallic compound, second organometallic compound, and solvent as described in one or more embodiments.

The resin may be a phenol-based resin including at least one aromatic moiety selected from moieties listed in Group 3.

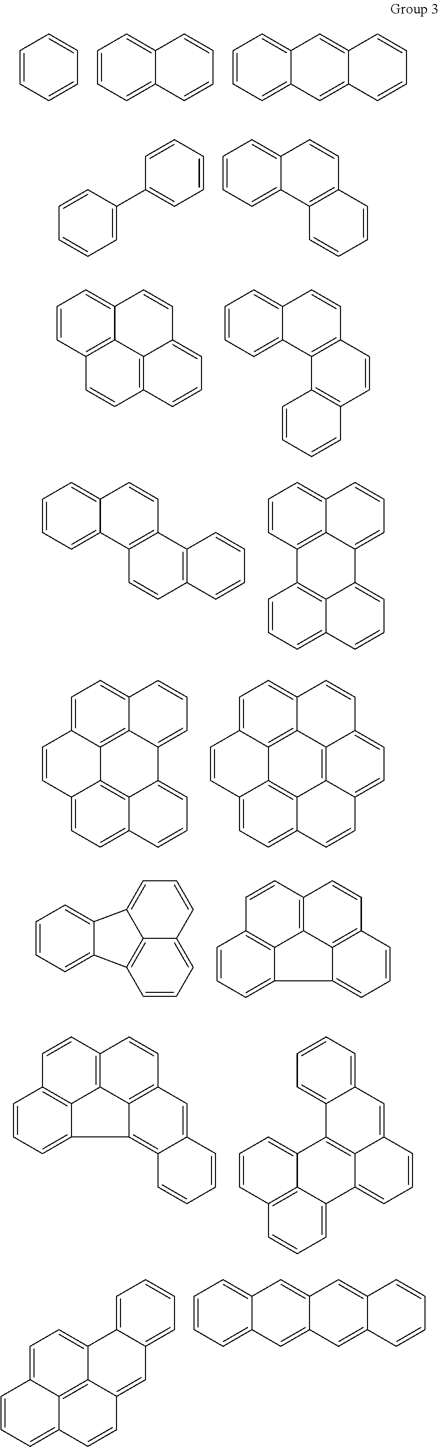

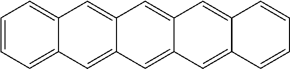 [SMILES: c1ccc2cc3cc4cc5ccccc5cc4cc3cc2c1]

The resin may have a weight average molecular weight (M_{w}) of about 500 g/mol to about 20,000 g/mol.

The resin may be included in an amount of about 0.1 wt % to about 50 wt % based on a total amount of the semiconductor photoresist composition (e.g., based on 100 wt % of the semiconductor photoresist composition).

If (e.g., when) the resin is included in the above content (e.g., amount) range, it may have excellent or suitable etch resistance and/or heat resistance.

In one or more embodiments, the semiconductor photoresist composition according to one or more embodiments may consist of or include the first organometallic compound, second organometallic compound, solvent, and resin as described in one or more embodiments. However, the semiconductor photoresist composition according to the one or more embodiments may further include additives as needed or desired. Examples of the additives may be a surfactant, a crosslinking agent, a leveling agent, an organic acid, a quencher, or a combination thereof.

The surfactant may include, for example, an alkyl benzene sulfonate salt, an alkyl pyridinium salt, polyethylene glycol, a quaternary ammonium salt, or a combination thereof, but embodiments of the present disclosure are not limited thereto.

The crosslinking agent may be, for example, a melamine-based crosslinking agent, a substituted urea-based crosslinking agent, an acryl-based crosslinking agent, an epoxy-based crosslinking agent, or a polymer-based crosslinking agent, but embodiments of the present disclosure are not limited thereto. It may be a crosslinking agent having at least two crosslinking forming substituents, for example, a compound, such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be used to improve or enhance coating flatness during printing and may be a commercially available or generally available leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but embodiments of the present disclosure are not limited thereto.

The quencher may be diphenyl (p-tolyl) amine, methyl diphenyl amine, triphenyl amine, phenylenediamine, naphthylamine, diaminonaphthalene, or a combination thereof.

A use amount of the additives may be controlled depending on desired properties.

In one or more embodiments, the semiconductor photoresist composition may further include a silane coupling agent as an adherence enhancer in order to improve or enhance a close-contacting force with the substrate (e.g., in order to improve or enhance adherence of the semiconductor photoresist composition to the substrate). The silane coupling agent may be, for example, a silane compound including a carbon-carbon unsaturated bond, such as vinyltrimethoxysilane, vinyl triethoxysilane, vinyl trichlorosilane, vinyl tris(β-methoxyethoxy)silane; or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy[3-(phenylamino)propyl]silane, and/or the like, but embodiments of the present disclosure are not limited thereto.

The semiconductor photoresist composition may be formed or provided into a pattern having a high aspect ratio without a collapse. In one or more embodiments, in order to form or provide a fine pattern having a width (e.g., a line width) of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, for example, about 5 nm to about 20 nm, or for example, about 5 nm to about 10 nm, the semiconductor photoresist composition may be used for a photoresist process using light having a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. In one or more embodiments, the semiconductor photoresist composition according to one or more embodiments may be used to realize extreme ultraviolet lithography using an EUV light source of a wavelength of about 13.5 nm.

According to according to one or more embodiments, a method of forming or providing patterns using the semiconductor photoresist composition as described in one or more embodiments may be provided. For example, the manufactured pattern may be a photoresist pattern.

The method of forming or providing patterns according to one or more embodiments may include forming or providing an etching-objective layer on a substrate, coating the semiconductor photoresist composition on the etching-objective layer to form or provide a photoresist layer, patterning the photoresist layer to form or provide a photoresist pattern, and etching the etching-objective layer utilizing the photoresist pattern as an etching mask.

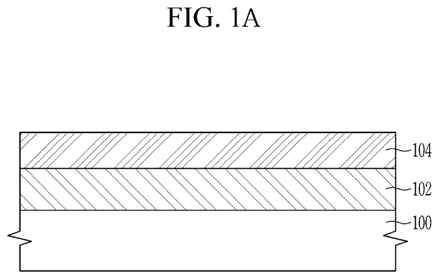

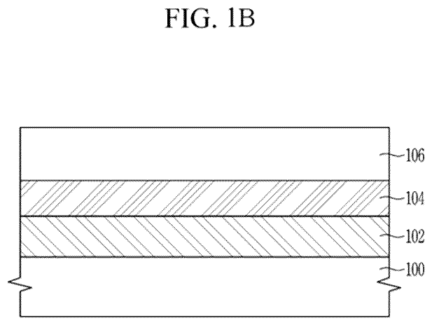

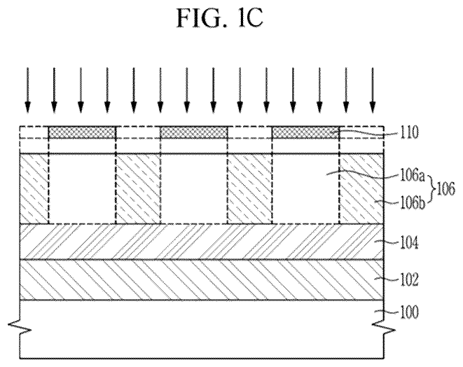

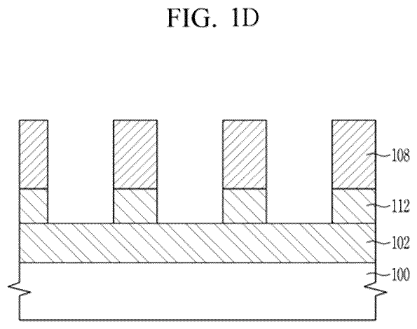

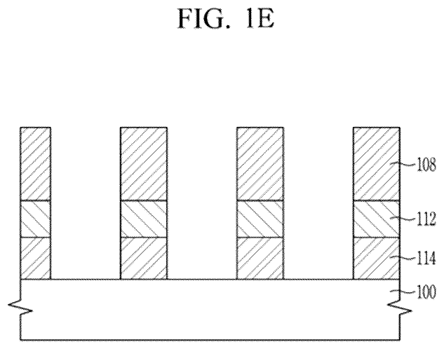

Hereinafter, a method of forming or providing patterns using the semiconductor photoresist composition is described referring to FIGS. 1A-1E. FIGS. 1A-1E each is a cross-sectional view for illustrating a method of forming or providing patterns using a semiconductor photoresist composition according to one or more embodiments.

Referring to FIG. 1A, an object for etching (e.g., etching objective layer or etching-target layer) may be prepared. The object for etching may be a thin film 102 on a semiconductor substrate 100. Hereinafter, the object for etching may be limited to the thin film 102. A surface of the thin film 102 may be washed to remove impurities and/or the like remaining thereon. The thin film 102 may be, for example, a silicon nitride layer, a polysilicon layer, and/or a silicon oxide layer.

Subsequently, the resist underlayer composition for providing a resist underlayer 104 may be spin-coated on the surface of the washed thin film 102. However, embodiments of the present disclosure are not limited thereto, and one or more suitable coating methods, for example, a spray coating, a dip coating, a knife edge coating, a printing method, for example, an inkjet printing and a screen printing, and/or the like, may be used.

The coating process of the resist underlayer may not be provided, and hereinafter, a process including a coating of the resist underlayer is described.

Then, the coated composition may be dried and baked (thermal treatment) to form or provide a resist underlayer 104 on the thin film 102. The baking (thermal treatment) may be performed at about 100° C. to about 500° C., for example, about 100° C. to about 300° C.

The resist underlayer 104 may be between the substrate 100 and a photoresist layer 106 and thus may prevent or reduce non-uniformity (e.g., substantial non-uniformity) and pattern formability of a photoresist line width if (e.g., when) a ray reflected from on the interface between the substrate 100 and the photoresist layer 106 or a hardmask between layers is scattered into an unintended photoresist region.

Referring to FIG. 1B, the photoresist layer 106 may be formed or provided by coating the semiconductor photoresist composition on the resist underlayer 104. The photoresist layer 106 may be obtained by coating the semiconductor photoresist composition according to one or more embodiments on the thin film 102 that is formed or provided on the substrate 100 and then, curing it through a heat treatment.

For example, the formation of a pattern by using the semiconductor photoresist composition may include coating the semiconductor resist composition on the substrate 100 having the thin film 102 through spin coating, slit coating, inkjet printing, and/or the like and then, drying it to form or provide the photoresist layer 106.

The semiconductor photoresist composition has already been illustrated in more detail and will not be illustrated again.

Subsequently, a substrate 100 having the photoresist layer 106 may be subjected to a first baking (thermal treatment) process. The first baking process may be performed at about 80° C. to about 120° C.

Referring to FIG. 1C, the photoresist layer 106 may be selectively exposed using a patterned mask 110.

For example, the exposure may use an activation radiation with light having a high energy wavelength, such as EUV (extreme ultraviolet; a wavelength of about 13.5 nm), an E-Beam (an electron beam), and/or the like, as well as light having a short wavelength, such as an i-line (a wavelength of about 365 nm), a KrF excimer laser (a wavelength of about 248 nm), an ArF excimer laser (a wavelength of about 193 nm), and/or the like.

For example, light or beam for the exposure according to one or more embodiments may have a short wavelength in a range of about 5 nm to about 150 nm and/or a high energy wavelength, for example, EUV (extreme ultraviolet; a wavelength of 13.5 nm), an E-Beam (an electron beam), and/or the like.

The exposed region 106b of the photoresist layer 106 may have a different solubility from the unexposed region 106a of the photoresist layer 106 by forming or providing a polymer by a crosslinking reaction, such as condensation between organometallic compounds (e.g., a condensation reaction between organometallic compounds).

Subsequently, the substrate 100 may be subjected to a second baking (thermal treatment) process. The second baking process may be performed at a temperature of about 90° C. to about 200° C. The exposed region 106b of the photoresist layer 106 may become easily indissoluble regarding a developer due to the second baking process.

In FIG. 1D, the unexposed region 106a of the photoresist layer may be dissolved and removed using the developer to form or provide a photoresist pattern 108. For example, the unexposed region 106a of the photoresist layer may be dissolved and removed by using an organic solvent, such as 2-heptanone and/or the like, to complete the photoresist pattern 108 corresponding to the negative tone image.

In one or more embodiments, a developer used in a method of forming or providing patterns according to one or more embodiments may be an organic solvent. The organic solvent used in the method of forming or providing patterns according to one or more embodiments may be, for example, ketones, such as methylethylketone, acetone, cyclohexanone, 2-heptanone, and/or the like, alcohols, such as 4-methyl-2-propanol, 1-butanol, isopropanol, 1-propanol, methanol, and/or the like, esters, such as propylene glycol monomethyl ether acetate, ethyl acetate, ethyl lactate, n-butyl acetate, butyrolactone, and/or the like, aromatic compounds, such as benzene, xylene, toluene, and/or the like, or a combination thereof.

However, the photoresist pattern according to one or more embodiments is not necessarily limited to the negative tone image but may be formed or provided to have a positive tone image. In one or more embodiments, a developer used to form or provide the positive tone image may be a quaternary ammonium hydroxide composition, such as tetraethylammonium hydroxide, tetrapropylammonium hydroxide, tetrabutylammonium hydroxide, or a combination thereof.

In one or more embodiments, exposure to light or beam having a high energy wavelength, such as EUV (extreme ultraviolet; a wavelength of 13.5 nm), an E-Beam (an electron beam), and/or the like, as well as light having a short wavelength, such as i-line (wavelength of about 365 nm), KrF excimer laser (wavelength of about 248 nm), ArF excimer laser (wavelength of about 193 nm), and/or the like, may provide a photoresist pattern 108 having a width of a thickness of about 5 nm to about 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

In one or more embodiments, the photoresist pattern 108 may have a pitch having (with) a half-pitch of less than or equal to about 50 nm, for example, less than or equal to about 40 nm, for example, less than or equal to about 30 nm, for example, less than or equal to about 20 nm, or, for example, less than or equal to about 10 nm, and a line width roughness of less than or equal to about 5 nm, less than or equal to about 3 nm, less than or equal to about 2 nm, or less than or equal to about 1 nm.

Subsequently, the photoresist pattern 108 may be used as an etching mask to etch the resist underlayer 104. Through this etching process, an organic layer pattern 112 may be formed or provided. The organic layer pattern 112 also may have a width (e.g., a line width) corresponding to that of the photoresist pattern 108.

Referring to FIG. 1E, the exposed thin film 102 may be etched by applying the photoresist pattern 108 as an etching mask. As a result, the thin film may be formed or provided as a thin film pattern 114.

The etching of the thin film 102 may be, for example, dry etching using an etching gas, and the etching gas may be, for example, CHF₃, CF₄, Cl₂, BCl₃, and/or a mixed gas thereof.

In the exposure process, the thin film pattern 114 that is formed or provided by utilizing the photoresist pattern 108 that is formed or provided through the exposure process performed by using an EUV light source may have a width (e.g., a line width) corresponding to that of the photoresist pattern 108. For example, the thin film pattern 114 may have a width (e.g., a line width) of about 5 nm to about 100 nm which may be equal to that of the photoresist pattern 108. For example, the thin film pattern 114 that is formed or provided by utilizing the photoresist pattern 108 that is formed or provided through the exposure process performed by using an EUV light source may have a width (e.g., a line width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and, for example, a width (e.g., a line width) of less than or equal to about 20 nm, like or substantially similar to that of the photoresist pattern 108.

Hereinafter, the present disclosure will be described in more detail through examples of the preparation of the semiconductor photoresist composition according to one or more embodiments. However, one or more embodiments of the present disclosure are technically not restricted by the following examples.

### Synthesis of First Organometallic Compound

### Synthesis Example 1

In a 250 mL 2-necked round-bottom flask, 20 g (51.9 mmol) of triphenyltin chloride (Ph₃SnCl) was dissolved in 70 mL of tetrahydrofuran (THF) and then, cooled to 0° C. in an ice bath. Subsequently, a 1 M tert-butyl magnesium chloride (tBuMgCl) THE solution (62.3 mmol) was slowly added thereto in a dropwise fashion. After the dropwise addition was completed, the obtained mixture was stirred at room temperature (25±3° C.) for 12 hours, obtaining a t-BuSnPh₃ compound.

Then, t-BuSnPh₃ (10 g, 24.6 mmol) was dissolved in 50 mL of dichloromethane (CH₂Cl₂), and 3 equivalents (73.7 mmol) of a 2 M hydrogen chloride (HCl) diethyl ether solution was slowly added thereto in a dropwise fashion at −78° C. for 30 minutes. After stirring the obtained mixture at room temperature for 12 hours, the solvent thereof was concentrated and vacuum-distilled, obtaining a t-BuSnCl₃ compound.

Then, 32 mL of propionic acid was slowly added in a dropwise fashion to 10 g (25.6 mmol) of t-BuSnCl₃ at room temperature and then, refluxed by heating for 12 hours. After increasing the temperature to room temperature, the propionic acid was vacuum distilled, obtaining a compound represented by Chemical Formula 1a.

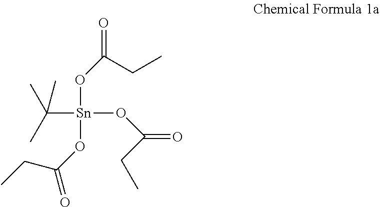 [SMILES: CCC(=O)[O][Sn]([O]C(=O)CC)([O]C(=O)CC)[C](C)(C)C]

### Synthesis Example 2

A compound represented by Chemical Formula 1b was obtained in substantially the same manner as in Synthesis Example 1 except that neopentyl magnesium chloride (neopentyl MgCl) was used instead of the t-butyl magnesium chloride (tBuMgCl).

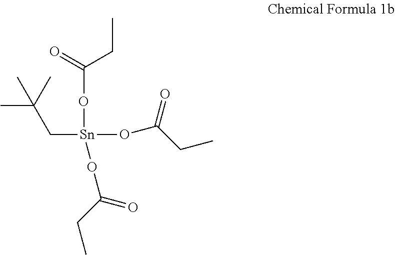 [SMILES: CCC(=O)[O][Sn]([CH2]C(C)(C)C)([O]C(=O)CC)[O]C(=O)CC]

### Synthesis Example 3

A compound represented by Chemical Formula 1c was obtained in substantially the same manner as in Synthesis Example 1 except that isobutyl magnesium chloride (iBuMgCl) was used instead of the t-butyl magnesium chloride (tBuMgCl).

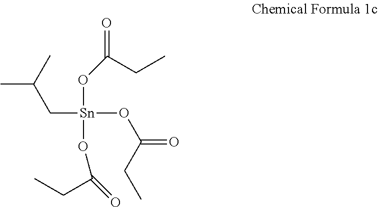 [SMILES: CCC(=O)[O][Sn]([CH2]C(C)C)([O]C(=O)CC)[O]C(=O)CC]

### Synthesis Example 4

A compound represented by Chemical Formula 1d was obtained in substantially the same manner as in Synthesis Example 1 except that normal butyl magnesium chloride (nBuMgCl) was used instead of the t-butyl magnesium chloride (tBuMgCl).

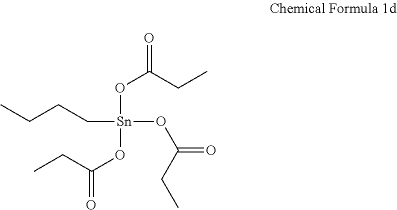 [SMILES: CCC[CH2][Sn]([O]C(=O)CC)([O]C(=O)CC)[O]C(=O)CC]

### Synthesis Example 5

In a 250 mL 2-necked round-bottom flask, 20 g (51.9 mmol) of Ph₃SnCl was dissolved in THE of 70 ml and then, cooled to 0° C. in an ice bath. Subsequently, a 1 M tertbutyl magnesium chloride (tBuMgCl) THE solution (62.3 mmol) was slowly added in a dropwise fashion thereto. When the dropwise addition was completed, the obtained mixture was stirred at room temperature for 12 hours, obtaining a compound of t-BuSnPh₃ at a yield of 89%.

Subsequently, t-BuSnPh₃ (10 g, 24.6 mmol) was dissolved in 50 mL of CH₂Cl₂, and 3 equivalent (73.7 mmol) of a 2 M HCl diethyl ether solution was slowly added in a dropwise fashion thereto at −78° C. for 30 minutes. After stirring the mixture at room temperature for 12 hours, the solvent thereof was concentrated and vacuum-distilled, obtaining a compound of t-BuSnCl₃.

Subsequently, 30 mL of anhydrous pentane was added to 10 g (35.4 mmol) of t-BuSnCl₃ and then, cooled to 0° C. Then, 7.8 g (106.3 mmol) of diethylamine was slowly added in a dropwise fashion thereto, and 10.9 g (106.3 mmol) of methyl isobutyl carbinol was added thereto and then, stirred at room temperature for 1 hour. When a reaction was completed, the resultant was filtered, concentrated, and vacuum-dried, obtaining a compound represented by Chemical Formula 1e at a yield of 60%.

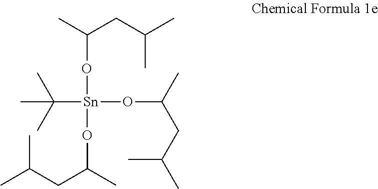 [SMILES: CC(C)CC(C)[O][Sn]([O]C(C)CC(C)C)([O]C(C)CC(C)C)[C](C)(C)C]

### Synthesis Example 6

A compound represented by Chemical Formula 1f was obtained with a yield of 60% by referring to the synthesis method described in Publication No. KR10-2020-0126884.

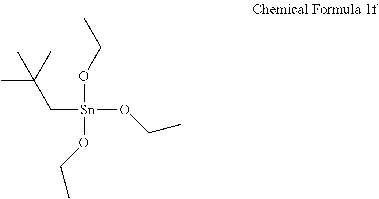

### Synthesis of Second Organometallic Compound

### Synthesis Example 7

A compound represented by Chemical Formula 2a was obtained in substantially the same manner as Synthesis Example 5 except that neopentyl magnesium chloride (neopentyl MgCl) instead of the t-butyl magnesium chloride (t-BuMgCl) and N-methylpropionamide instead of the methyl isobutyl carbinol were used.

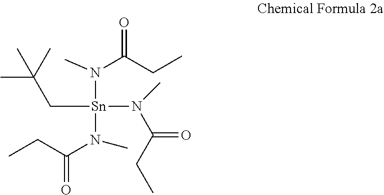 [SMILES: CCC(=O)[N](C)[Sn]([CH2]C(C)(C)C)([N](C)C(=O)CC)[N](C)C(=O)CC]

### Synthesis Example 8

A compound represented by Chemical Formula 2b was obtained in substantially the same manner as Synthesis Example 5 except that isobutyl magnesium chloride (iBuMgCl) instead of the t-butyl magnesium chloride (t-BuMgCl) and methyl phosphonic acid instead of the methyl isobutyl carbinol were used.

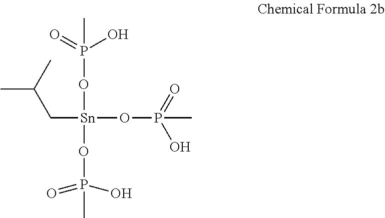 [SMILES: CC(C)[CH2][Sn]([O]P(C)(=O)O)([O]P(C)(=O)O)[O]P(C)(=O)O]

### Synthesis Example 9

A compound represented by Chemical Formula 2c was obtained in substantially the same manner as Synthesis Example 5 except that normal butyl magnesium chloride (nBuMgCl) instead of the t-butyl magnesium chloride (t-BuMgCl) and triflic acid instead of the methyl isobutyl carbinol were used.

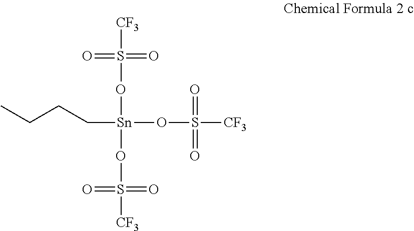 [SMILES: CCC[CH2][Sn]([O]S(=O)(=O)C(F)(F)F)([O]S(=O)(=O)C(F)(F)F)[O]S(=O)(=O)C(F)(F)F]

### Preparation of Semiconductor Photoresist Compositions

### Examples 1 to 14 and Comparative Example 1 to 7

Each of the compounds represented by Chemical Formulas 1a to 1f and 2a to 2c according to Synthesis Examples 1 to 9 was dissolved in propylene glycol monomethyl ether acetate (PGMEA) at 3 wt % and then, filtered with a 0.1 μm polytetrafluoroethylene (PTFE) syringe filter, preparing a photoresist composition.

### Evaluation 1: Evaluation of Coating Surface Roughness

Each of the photoresist compositions according to Examples 1 to 14 and Comparative Examples 1 to 7 was coated on a wafer and exposed at 100° C. on a hot plate for 60 seconds to measure surface roughness (R_{q}) by using an atomic force microscope (AFM). The results are evaluated according to the following criteria and then, shown in Table 1.

### Surface Roughness (R_{q} Value)

∘: less than or equal to 0.4
Δ: greater than 0.4 and less than or equal to 0.7
X: greater than 0.7

### Evaluation 2: Evaluation of Line Edge Roughness (LER)

A line array of 50 circular pads having a diameter of 500 μm was projected onto the wafer coated with each photoresist composition of Examples 1 to 14 and Comparative Examples 1 to 7, by using EUV light (Lawrence Berkeley National Laboratory Micro Exposure Tool, MET). Herein, exposure time of the pads was adjusted to apply an increased EUV dose to each pad.

Subsequently, the resist and the substrate were exposed on a hot plate at 160° C. for 120 seconds and then, baked. The baked film was immersed in a developer (2-heptanone) for 30 seconds each, and then washed with the same developer (2-heptanone) for an additional 10 seconds to form or provide a negative tone image, that is, to remove the unexposed portion of the coating. Finally, the hot plate was baked at 150° C. for 2 minutes, completing the process.

An electron microscope was used to measure line edge roughness (LER) of a line & space pattern. The results are evaluated according to the following criteria and then, shown in Table 1.

### Line Edge Roughness (LER)

∘: less than or equal to 4 nm
Δ: greater than 4 nm and less than or equal to 7 nm
X: greater than 7 nm

TABLE 1

| | First | Second | | | |
|---|---|---|---|---|---|
| | organo- | organo- | | Surface | |
| | metallic | metallic | Weight | roughness | |
| | compound | compound | ratio | (Rg) | LER |
| Example 1 | Chemical | Chemical | 70:30 | Δ | ◯ |
| | Formula 1a | Formula 2a | | | |
| Example 2 | Chemical | Chemical | 90:10 | ◯ | ◯ |
| | Formula 1a | Formula 2b | | | |
| Example 3 | Chemical | Chemical | 90:10 | Δ | ◯ |
| | Formula 1b | Formula 2c | | | |
| Example 4 | Chemical | Chemical | 70:30 | ◯ | Δ |
| | Formula 1b | Formula 2a | | | |
| Example 5 | Chemical | Chemical | 90:10 | ◯ | ◯ |
| | Formula 1b | Formula 2b | | | |
| Example 6 | Chemical | Chemical | 90:10 | Δ | Δ |
| | Formula 1b | Formula 2c | | | |
| Example 7 | Chemical | Chemical | 70:30 | ◯ | Δ |
| | Formula 1c | Formula 2a | | | |
| Example 8 | Chemical | Chemical | 90:10 | ◯ | Δ |
| | Formula 1c | Formula 2b | | | |
| Example 9 | Chemical | Chemical | 90:10 | Δ | Δ |
| | Formula 1c | Formula 2c | | | |
| Example 10 | Chemical | Chemical | 70:30 | Δ | Δ |
| | Formula 1d | Formula 2a | | | |
| Example 11 | Chemical | Chemical | 90:10 | Δ | Δ |
| | Formula 1d | Formula 2b | | | |
| Example 12 | Chemical | Chemical | 90:10 | Δ | Δ |
| | Formula 1d | Formula 2c | | | |
| Example 13 | Chemical | Chemical | 70:30 | Δ | Δ |
| | Formula 1e | Formula 2a | | | |
| Example 14 | Chemical | Chemical | 70:30 | ◯ | Δ |
| | Formula 1f | Formula 2a | | | |
| Comparative | Chemical | — | — | X | Δ |
| Example 1 | Formula 1a | | | | |
| Comparative | Chemical | — | — | X | X |
| Example 2 | Formula 1b | | | | |
| Comparative | Chemical | — | — | X | X |
| Example 3 | Formula 1c | | | | |
| Comparative | Chemical | — | — | X | X |
| Example 4 | Formula 1d | | | | |
| Comparative | — | Chemical | — | X | X |
| Example 5 | | Formula 2a | | | |
| Comparative | — | Chemical | — | X | X |
| Example 6 | | Formula 2b | | | |
| Comparative | — | Chemical | — | X | X |
| Example 7 | | Formula 2c | | | |

Referring to the result of Table 1, the photoresist compositions for a semiconductor according to Examples, compared to the photoresist compositions for a semiconductor according to Comparative Examples, exhibited excellent coating properties due to reduced surface roughness and excellent line edge roughness.

Hereinbefore, certain embodiments of the present disclosure have been described and illustrated, however, it should be apparent to a person having ordinary skill in the art that the present disclosure is not limited to the embodiments as described, and may be suitably modified and transformed without departing from the spirit and scope of the present disclosure. Accordingly, the modified or transformed embodiments as such may not be understood separately from the technical ideas and aspects of one or more embodiments of the present disclosure, and the modified embodiments may be within the scope of the appended claims and equivalents thereof of the present disclosure.

### DESCRIPTION OF SYMBOLS

| | |
|---|---|
| 100: substrate | 102: thin film |
| 104: resist underlayer | 106: photoresist layer |
| 106a: unexposed region | 106b: exposed region |
| 108: photoresist pattern | 112: organic layer pattern |
| 110: patterned mask | 114: thin film pattern |

What is claimed is:

1. A semiconductor photoresist composition, comprising:
a first organometallic compound represented by Chemical Formula 1;
a second organometallic compound represented by Chemical Formula 2; and
a solvent: 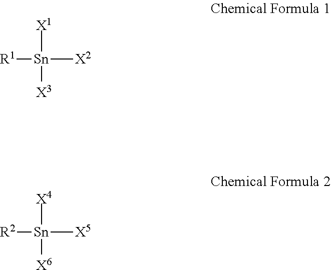
wherein, in Chemical Formula 1 and Chemical Formula 2,
R¹ and R² are each independently a substituted or unsubstituted C1 to C20 alkyl group, a substituted or unsubstituted C2 to C20 alkenyl group, a substituted or unsubstituted C2 to C20 alkynyl group, or -L^{a}-O—R^{a} (wherein L^{a} is a single bond or a substituted or unsubstituted C1 to C20 alkylene group, and R^{a} is a substituted or unsubstituted C1 to C20 alkyl group),
X¹ to X³ are each independently selected from among an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof),
X⁴ to X⁶ are each independently selected from among an amino, alkylamine, or dialkylamine group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an amido group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an amidinate group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an alkylthio or arylthio group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), a phosphinate group (—OP(O)OR^{m}Rⁿ, wherein R^{m} and Rⁿ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), and a sulfonate group (—OS(O)₂R^{o}, wherein R^{o} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof).

2. The semiconductor photoresist composition as claimed in claim 1, wherein:
R¹ and R² are each independently a substituted or unsubstituted C1 to C10 alkyl group, a substituted or unsubstituted C2 to C10 alkenyl group, a substituted or unsubstituted C2 to C10 alkynyl group, or -L^{a}-O—R^{a} (wherein L^{a} is a single bond or a substituted or unsubstituted C1 to C20 alkylene group, and R^{a} is a substituted or unsubstituted C1 to C20 alkyl group),
X¹ to X³ are each independently selected from among an alkoxy or aryloxy group (—OR^{b}, wherein R^{b} is a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), and a carboxyl group (—O(CO)R^{c}, wherein R^{c} is hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), and
X⁴ to X⁶ are each independently an amino, alkylamine, or dialkylamine group (—NR^{d}R^{e}, wherein R^{d} and R^{e} are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), an amido group (—NR^{f}(COR^{g}), wherein R^{f} and R^{g} are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), or an amidinate group (—NR^{h}C(NRⁱ)R^{j}, wherein R^{h}, Rⁱ, and Rⁱ are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), an alkylthio or arylthio group (—SR^{k}, wherein R^{k} is a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), a thiocarboxyl group (—S(CO)R^{l}, wherein R^{l} is hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), a phosphinate group (—OP(O)OR^{m}Rⁿ, wherein R^{m} and Rⁿ are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), and a sulfonate group (—OS(O)₂R^{o}, wherein R^{o} is hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof).

3. The semiconductor photoresist composition as claimed in claim 1, wherein:
R¹ and R² are each independently a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted benzyl group, a substituted or unsubstituted methoxy group, a substituted or unsubstituted ethoxy group, a substituted or unsubstituted propoxy group, or a combination thereof,
R^{b} is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof, and
R^{c}, R^{d}, R^{e}, R^{f}, R^{g}, R^{h}, Rⁱ, R^{j}, R^{k}, R^{l}, R^{m}, Rⁿ, and R^{o} are each independently hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof.

4. The semiconductor photoresist composition as claimed in claim 1, wherein:
X⁴ to X⁶ are each independently selected from among an amino, alkylamine, or dialkylamine group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an amido group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), a phosphinate group (—OP(O)OR^{m}Rⁿ, wherein R^{m} and Rⁿ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), and a sulfonate group (—OS(O)₂R^{o}, wherein R^{o} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof).

5. The semiconductor photoresist composition as claimed in claim 1, wherein:
the first organometallic compound and the second organometallic compound are included in a weight ratio of about 90:10 to about 40:60.

6. The semiconductor photoresist composition as claimed in claim 1, wherein:
the first organometallic compound and the second organometallic compound are included in a weight ratio of about 70:30 to 40:60.

7. The semiconductor photoresist composition as claimed in claim 1, wherein:
the first organometallic compound is one selected from among the compounds listed in Group 1:

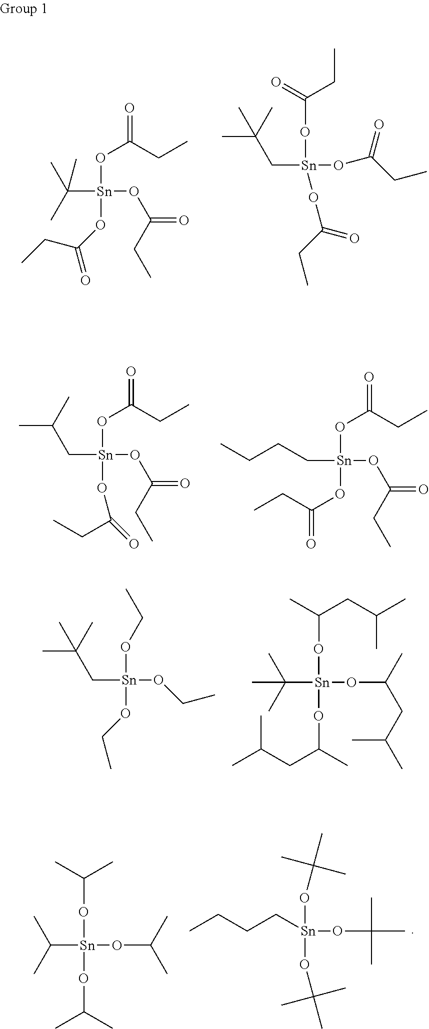

8. The semiconductor photoresist composition as claimed in claim 1, wherein:
the second organometallic compound is one selected from among the compounds listed in Group 2:

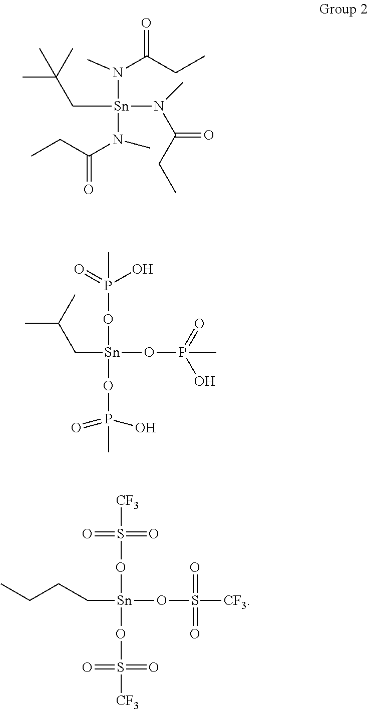

9. The semiconductor photoresist composition as claimed in claim 1, wherein:
the first organometallic compound and the second organometallic compound are included in an amount of about 1 wt % to about 30 wt % based on 100 wt % of the semiconductor photoresist composition.

10. The semiconductor photoresist composition as claimed in claim 1, wherein
the semiconductor photoresist composition further comprises an additive of a surfactant, a crosslinking agent, a leveling agent, an organic acid, a quencher, or a combination thereof.

11. A method of forming patterns, comprising:
providing an etching-objective layer on a substrate;
coating the semiconductor photoresist composition as claimed in claim 1 on the etching-objective layer to provide a photoresist layer;
patterning the photoresist layer to provide a photoresist pattern; and
etching the etching-objective layer utilizing the photoresist pattern as an etching mask.

12. The method as claimed in claim 11, wherein:
the photoresist pattern is provided using light having a wavelength of about 5 nm to about 150 nm.

13. The method as claimed in claim 11, wherein:
the method further comprises providing a resist underlayer between the substrate and the photoresist layer.

14. The method as claimed in claim 11, wherein:
the photoresist pattern has a width of about 5 nm to about 100 nm.
